(19) United States
(12) Patent Application Publication
(10) Pub. No.: US 2026/0150201 A1
(43) Pub. Date: May 28, 2026

(54) CASING, ELECTRONIC DEVICE, AND MOBILE BODY

(71) Applicant: Panasonic Automotive Systems Co., Ltd., Kanagawa (JP)

(72) Inventors: Tadahiro KUGIMARU, Osaka (JP); Takeshi HONDA, Hyogo (JP); Hideo SAKON, Osaka (JP)

(73) Assignee: Panasonic Automotive Systems Co., Ltd., Kanagawa (JP)

(21) Appl. No.: 19/365,485

(22) Filed: Oct. 22, 2025

(30) Foreign Application Priority Data
Nov. 22, 2024 (JP) 2024-203648

(51) Int. Cl. H05K 5/00; H05K 5/02; H05K 7/14

(52) U.S. Cl. CPC H05K 5/006; H05K 5/0052; H05K 5/0247; H05K 7/142

(57) ABSTRACT

A casing is made of metal and includes first component and a second component. The first component includes: a rectangular first face portion; a first standing portion standing from one crosswise-direction edge of the first face portion; and a second standing portion standing from the other crosswise-direction edge. The second component includes: a rectangular second face portion; a first contact portion standing from one crosswise-direction edge and overlapping the outer face of the first standing portion with contact therebetween; and a first overlap portion standing from the other crosswise-direction edge and overlapping the outer face of the second standing portion with a gap therebetween. At least one of the second standing portion or first overlap portion includes a first protruding portion that maintains a predetermined distance between the second standing portion and the first overlap portion and generates pressure between the first standing portion and the first contact portion.

### CROSS REFERENCE TO RELATED APPLICATION

The present application is based on and claims priority of Japanese Patent Application No. 2024-203648 filed on November 22, 2024.

### FIELD

The present disclosure relates to a casing that internally houses a substrate, to an electronic device, and to a mobile body.

### BACKGROUND ART

Conventionally, as described in each of Patent Literature (PTL) 1, 2, and 3, various techniques regarding a metal casing that houses a circuit board are disclosed.

### Citation List

### Patent Literature

PTL 1: Japanese Unexamined Patent Application Publication No. 2003-152379

PTL 2: Japanese Unexamined Patent Application Publication No. 2011-100891

PTL 3: Japanese Unexamined Patent Application Publication (Translation of PCT Application) No. 2005-527114

### SUMMARY

However, the metal casings described in PTL 1 to 3 can be improved upon.

In view of this, the present disclosure provides a casing, an electronic device, and a mobile body that are capable of improving upon the related art.

A casing according to an aspect of the present disclosure is a casing that is made of metal and houses a substrate, and includes: a first component and a second component that are arranged in a thickness direction of the substrate. The first component includes: a first face portion that is rectangular and covers a first principal face of the substrate; a first standing portion that stands from one edge of the first face portion in a crosswise direction of the first face portion; and a second standing portion that stands from an other edge of the first face portion in the crosswise direction. The second component includes: a second face portion that is rectangular and covers a second principal face disposed on a reverse side of the first principal face; a first contact portion that stands from one edge of the second face portion in the crosswise direction and overlaps an outer face of the first standing portion with contact therebetween; and a first overlap portion that stands from an other edge of the second face portion in the crosswise direction and overlaps an outer face of the second standing portion with a gap therebetween. At least one of the second standing portion or the first overlap portion includes a first protruding portion that maintains the gap between the second standing portion and the first overlap portion at a predetermined distance and generates pressure between the first standing portion and the first contact portion.

An electronic device according to an aspect of the present disclosure includes: a substrate; and a casing that is made of metal and houses the substrate. The casing includes a first component and a second component that are arranged in a thickness direction of the substrate. The first component includes: a first face portion that is rectangular and covers a first principal face of the substrate; a first standing portion that stands from one edge of the first face portion in a crosswise direction of the first face portion; and a second standing portion that stands from an other edge of the first face portion in the crosswise direction. The second component includes: a second face portion that is rectangular and covers a second principal face disposed on a reverse side of the first principal face; a first contact portion that stands from one edge of the second face portion in the crosswise direction and overlaps an outer face of the first standing portion with contact therebetween; and a first overlap portion that stands from an other edge of the second face portion in the crosswise direction and overlaps an outer face of the second standing portion with a gap therebetween. At least one of the second standing portion or the first overlap portion includes a first protruding portion that maintains the gap between the second standing portion and the first overlap portion at a predetermined distance and generates pressure between the first standing portion and the first contact portion.

A mobile body according to an aspect of the present disclosure is a mobile body that includes an electronic device including: a substrate; and a casing that is made of metal and houses the substrate. The casing includes a first component and a second component that are arranged in a thickness direction of the substrate. The first component includes: a first face portion that is rectangular and covers a first principal face of the substrate; a first standing portion that stands from one edge of the first face portion in a crosswise direction of the first face portion; and a second standing portion that stands from an other edge of the first face portion in the crosswise direction. The second component includes: a second face portion that is rectangular and covers a second principal face disposed on a reverse side of the first principal face; a first contact portion that stands from one edge of the second face portion in the crosswise direction and overlaps an outer face of the first standing portion with contact therebetween; and a first overlap portion that stands from an other edge of the second face portion in the crosswise direction and overlaps an outer face of the second standing portion with a gap therebetween. At least one of the second standing portion or the first overlap portion includes a first protruding portion that maintains the gap between the second standing portion and the first overlap portion at a predetermined distance and generates pressure between the first standing portion and the first contact portion.

A casing, an electronic device, and a mobile body according to an aspect of the present disclosure are capable of improving upon the related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 is a perspective view of a casing.

FIG. 2 is a perspective view of the disassembled casing from the X− side.

FIG. 3 is a perspective view of the disassembled casing from the X+ side.

FIG. 4 is a cross-sectional view of the casing taken along a YZ plane.

FIG. 5 is a perspective view of a state in which a substrate is placed on a first component.

FIG. 6 is a side view schematically illustrating a mobile body.

### DESCRIPTION OF EMBODIMENTS

Hereinafter, exemplary embodiments of a casing, an electronic device, and a mobile body according to the present disclosure will be described with reference to the drawings. It should be noted that each of the subsequent embodiments shows an example for describing the present disclosure, and thus is not intended to limit the present disclosure. For example, the shapes, structures, materials, structural components, the relative positional relationships and connections of the structural components, numerical values, formulas, steps, the processing order of the steps, and so on, shown in the following embodiments are mere examples, and details not described below may be included. Furthermore, although there are cases where geometric expressions, such as “parallel” and “orthogonal”, are used, these expressions are not mathematically precise indications and include substantially permissible error, deviation, and the like. Moreover, expressions such as “simultaneous” and “identical (or the same)” are considered to cover a substantially permissible range of meaning.

Additionally, the drawings are schematic illustrations that may include emphasis, omission, or adjustment of proportion as necessary for the purpose of describing the present disclosure, and thus the shapes, positional relationships, and proportions shown may be different from actuality. Furthermore, the X-axis, Y-axis, and Z-axis which may be shown in the drawings are arbitrarily set rectangular coordinates for describing the figures. In other words, the Z-axis is not limited to an axis in the vertical direction, and the X-axis and Y-axis are not limited to being axes inside a horizontal plane.

Furthermore, hereinafter, multiple inventions may be comprehensively described as a single embodiment. Moreover, part of the contents in the description below is described as an optional element related to the present disclosure.

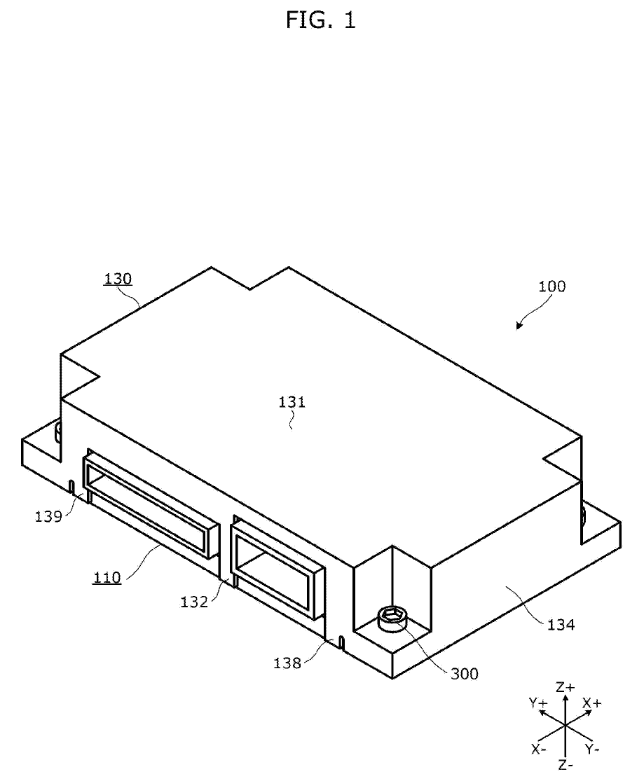

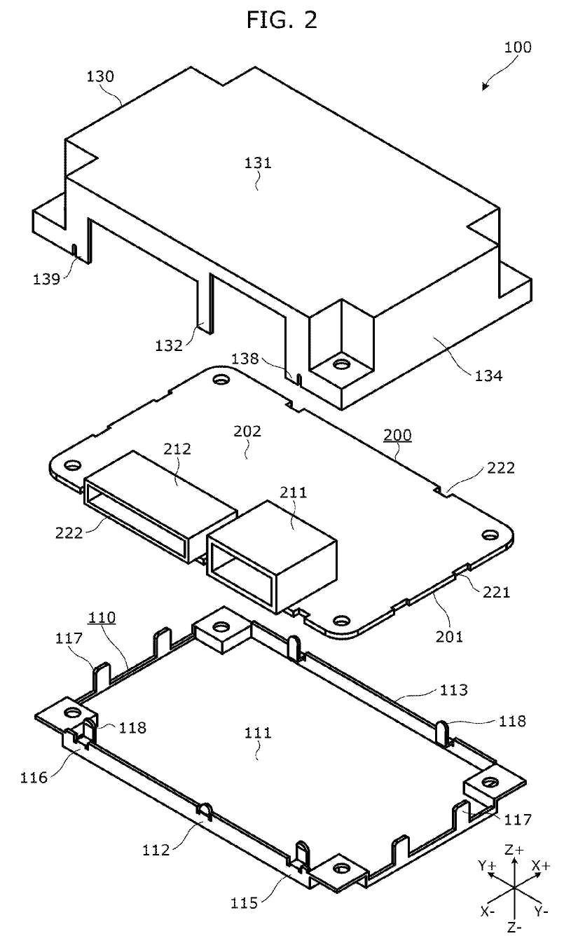

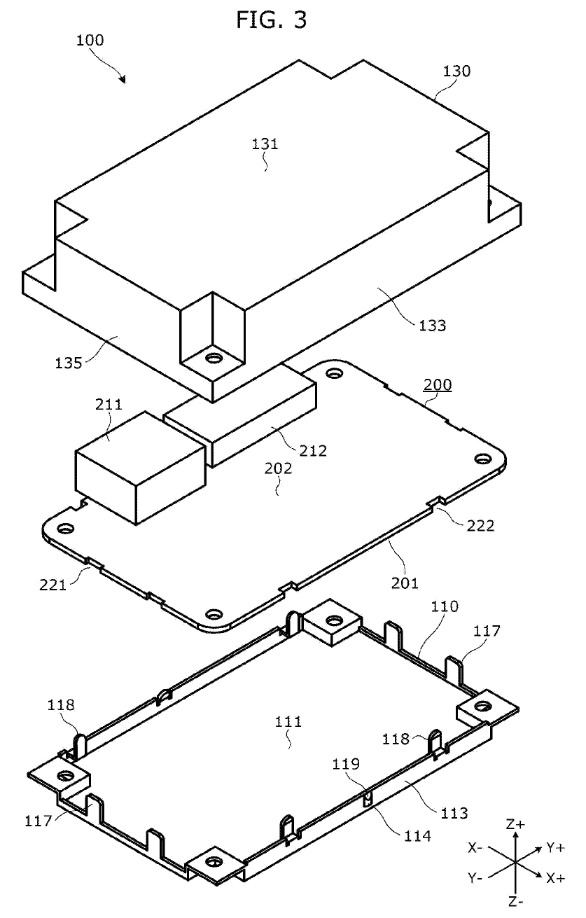

FIG. 1 is a perspective view of casing 100. FIG. 2 is a perspective view of disassembled casing 100 from the X− side. FIG. 3 is a perspective view of disassembled casing 100 from the X+ side. Casing 100 is made of metal and physically and electrically protects internally housed substrate 200. Casing 100 includes first component 110, second component 130, and first protruding portion 114 that are arranged in the thickness direction (the Z-axis direction in the figures) of internally housed substrate 200. The metal making up casing 100 is not limited, and may be a simple metal or an alloy. Furthermore, casing 100 may include on its surfaces a protective film, such as an anti-corrosion film, formed by surface processing, or the like.

Substrate 200 includes a printed circuit board having wiring applied thereon, and circuit components such as electronic components, electrical components, and so on, that are mounted on the printed circuit board. The type of the circuit that is formed by the circuit components that are electrically connected by substrate 200 is not limited and, in the present embodiment, a circuit that generates noise of a particular frequency is assumed for substrate 200.

First component 110 is a box-shaped component that covers substrate 200 on one side (the Z− side in the figures) in the thickness direction of substrate 200 that is housed, and includes first face portion 111, first standing portion 112, and second standing portion 113.

In first component 110, first face portion 111 is a rectangular part that covers first principal face 201 of substrate 200. Principal faces refer to the pair faces of tabular substrate 200 that have the largest area. Rectangular (rectangle-shaped) refers to a shape that can be considered a rectangle when first face portion 111 is viewed from the thickness direction of substrate 200, and may have a cutout, a protrusion, or the like, in one part thereof, or may have rounded corners, and so on. Covering first principal face 201 includes the case where the majority of first principal face 201 is covered as well as the case where the entirety of first principal face 201 is covered, when viewed from the thickness direction of substrate 200.

First standing portion 112 is part of a wall portion that stands from one edge (the X− side edge) of first face portion 111 in the crosswise direction (the X-axis direction in the figures) of first face portion 111. First standing portion 112 is a part that comes into contact with first contact portion 132 to be described later. In the present embodiment, first standing portion 112 is disposed at a position that is offset from the center portion in the lengthwise direction (the Y-axis direction in the figures) of first face portion 111.

Second standing portion 113 is a wall portion that stands from the other edge (the X+ side edge in the figure) of first face portion 111 in the crosswise direction. In the present embodiment, first standing portion 112 and second standing portion 113 are disposed so as to be orthogonal to the crosswise direction.

In the present embodiment, first component 110 includes: third standing portion 115 that stands at a position that is aligned with first standing portion 112 in the lengthwise direction of first face portion 111 and comes into contact with third contact portion 138 to be described later; and fourth standing portion 116 that stands at a position that is aligned with third standing portion 115 in the lengthwise direction, with first standing portion 112 disposed therebetween, and comes into contact with fourth contact portion 139 to be described later. In the present embodiment, like first standing portion 112, third standing portion 115 and fourth standing portion 116 are part of a wall portion that stands from the one edge of first face portion 111.

Second component 130 is a box-shaped component that covers substrate 200 on the other side (the Z+ side in the figures) in the thickness direction of substrate 200 that is housed, and includes second face portion 131, first contact portion 132, and first overlap portion 133.

Second face portion 131 is a rectangular part that covers second principal face 202 disposed on the reverse side of first principal face 201. Covering second principal face 202 includes the case where the majority of second principal face 202 is covered as well as the case where the entirety of second principal face 202 is covered, when viewed from the thickness direction of substrate 200.

First contact portion 132 is a part that stands from one edge (the X− side edge) of second face portion 131 in the crosswise direction and overlaps the outer surface of first standing portion 112 of first component 110 with contact therebetween. In the present embodiment, first contact portion 132 is a strip-shaped part disposed at a position that is offset from the center portion in the lengthwise direction of second face portion 131.

In the present embodiment, second component 130 includes third contact portion 138 that stands from the one edge of second face portion 131 in the crosswise direction and overlaps the outer surface of third standing portion 115 with contact therebetween. Second component 130 includes fourth contact portion 139 that stands from the one edge of second face portion 131 and overlaps the outer surface of fourth standing portion 116 with contact therebetween. Fourth standing portion 116 is disposed at a position that is aligned with third standing portion 115 in the lengthwise direction, with first standing portion 112 disposed therebetween.

First connector 211 that is to be attached to substrate 200 is disposed between (i) first standing portion 112 and first contact portion 132 that are in contact with each other and (ii) third standing portion 115 and third contact portion 138 that are in contact with each other. Furthermore, second connector 212 that is to be attached to substrate 200 is also disposed between (i) first standing portion 112 and first contact portion 132 that are in contact with each other and (ii) fourth standing portion 116 and fourth contact portion 139 that are in contact with each other. First connector 211 and second connector 212 are components that penetrate through casing 100 from the inside to the outside. First connector 211 and second connector 212 are connectors for obtaining communication, supply of power, and signals from a sensor, from the outside of casing 100. At least one of first connector 211 or second connector 212 is electrically connected to common wiring (earth wiring) of substrate 200.

First overlap portion 133 is a wall part that stands from the other edge (the X+ side edge in the figures) of second face portion 131 and overlaps the outer surface of second standing portion 113 with a gap therebetween.

In the crosswise direction (the X-axis direction in the figures), first protruding portion 114 is a part that is disposed between second standing portion 113 and first overlap portion 133 in order to maintain the gap between second standing portion 113 and first overlap portion 133 at a predetermined distance. It is sufficient that first protruding portion 114 be attached to either one of second standing portion 113 or first overlap portion 133. In the present embodiment, first protruding portion 114 is integrally provided in an outwardly protruding state from second standing portion 113. The shape of first protruding portion 114 is not limited. In the present embodiment, first protruding portion 114 has a shape that is obtained by cutting a column along a plane that is parallel to its center axis, and sloped portion 119 which slopes toward second standing portion 113 with proximity to second component 130 is provided at the end portion of first protruding portion 114 that is closer to second component 130. First protruding portion 114 maintains the gap between second standing portion 113 and first overlap portion 133 at a predetermined distance to thereby cause first standing portion 112 and first contact portion 132 to be in close contact, and generate predetermined pressure between first standing portion 112 and first contact portion 132. Consequently, in the crosswise direction, a firm fit is created between first component 110 and second component 130.

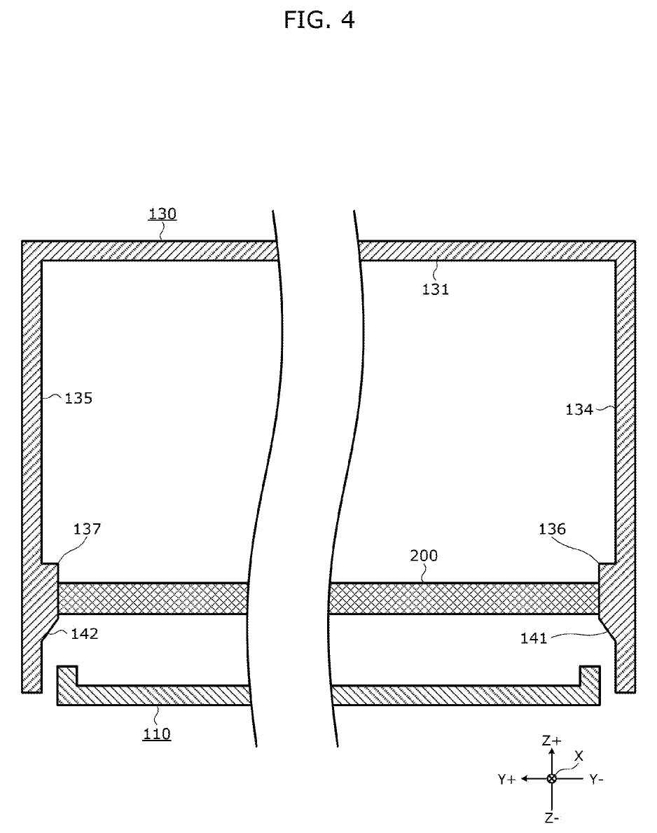

FIG. 4 is a cross-sectional view of casing 100 taken along a YZ plane. In the present embodiment, second component 130 includes second overlap portion 134, third overlap portion 135, second protruding portion 136, and third protruding portion 137.

Second overlap portion 134 and third overlap portion 135 are wall portions that rise up from opposite edges of second face portion 131 in the lengthwise direction of second face portion 131, and overlap edges of substrate 200 with a predetermined gap therebetween. In the present embodiment, second overlap portion 134 and third overlap portion 135 partially overlap first component 110 in the lengthwise direction with a predetermined gap therebetween.

Second protruding portion 136 and third protruding portion 137 are parts that protrude toward substrate 200 from the inner faces of second overlap portion 134 and third overlap portion 135, respectively. Second protruding portion 136 and third protruding portion 137 abut edges of substrate 200 to thereby determine the position of second component 130 relative to substrate 200 in the lengthwise direction of substrate 200 and determine the position of second component 130 relative to first component 110 via substrate 200. Accordingly, in the lengthwise direction, a gap is formed between (i) first component 110 and (ii) second overlap portion 134 and third overlap portion 135, and thus (i) first component 110 and (ii) second overlap portion 134 and third overlap portion 135 do not come into contact in the lengthwise direction. In the present embodiment, first tapered portion 141 and second tapered portion 142 which guide second component 130 along the edges of substrate 200 are provided in the first component 110-side end portions of second protruding portion 136 and third protruding portion 137, respectively.

The shape of each of second protruding portion 136 and third protruding portion 137 is not limited and, in the present embodiment, is a semi-columnar shape obtained by cutting a columnar shape along a plane that includes its center axis.

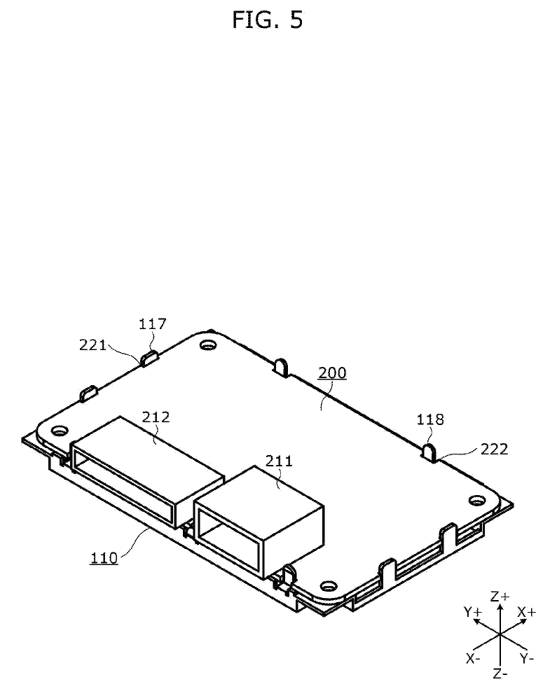

FIG. 5 is a perspective view of a state in which substrate 200 is placed on first component 110. First component 110 includes, at predetermined positions, first claw portions 117 and second claw portions 118 that protrude toward second component 130. First claw portions 117 protrude, in an upright state, from the lengthwise direction edge portions of first face portion 111. Second claw portions 118 rise up toward second component 130, then curve inward, and rise up again toward second component 130 to form a so-called crank shape. Substrate 200 includes first notch portions 221 and second notch portions 222 that have shapes corresponding to first claw portion 117 and second claw portion 118. When substrate 200 is placed on first component 110, first claw portions 117 engage with first notch portions 221, and second claw portions 118 engage with second notch portions 222. Accordingly, the position of substate 200 relative to first component 110 is determined.

Next, second component 130 is brought closer to substrate 200 and first component 110 to cover substrate 200 and first component 110. In the lengthwise direction, first tapered portion 141 and second tapered portion 142 guide second component 130 with respect to substrate 200, and second protruding portion 136 and third protruding portion 137 abut the lengthwise direction edge portions of substrate 200. This determines the positions of first component 110, substrate 200, and second component 130 in the lengthwise direction. The tips of first contact portion 132, third contact portion 138, and fourth contact portion 139 overlap first standing portion 112, third standing portion 115, and fourth standing portion 116, respectively, in the lengthwise direction while being guided by the curved parts of second claw portions 118.

Meanwhile, first overlap portion 133 is guided by sloped portion 119 located in the end portion of first protruding portion 114 so that the distance between (i) first overlap portion 133 and (ii) first contact portion 132, third contact portion 138, and fourth contact portion 139 increases. The friction that is generated between (i) first contact portion 132, third contact portion 138, and fourth contact portion 139 and (ii) first standing portion 112, third standing portion 115, and fourth standing portion 116 at this time causes the highly-insulative coating present on the surfaces of first component 110 and second component 130 to peel off, and thus electrical contact between (i) first contact portion 132, third contact portion 138, and fourth contact portion 139 and (ii) first standing portion 112, third standing portion 115, and fourth standing portion 116 is ensured.

In the state in which substrate 200 is sandwiched in the thickness direction by first component 110 and second component 130, first component 110 and second component 130 are fastened in the thickness direction of substrate 200 by fastening components 300. With this, casing 100 is completed, and an electronic device in which substrate 200 is housed inside casing 100 is manufactured.

Second component 130 is electrically connected to the common wiring (earth wiring) of substrate 200 at the fastening parts of fastening components 300. Here, even when substrate 200 emits a noise for which the distance between two fastening components 300 aligned in the lengthwise direction is equivalent to one-nth (i.e., a fraction) of the wavelength of the noise (where n is an integer), since first contact portion 132 and first standing portion 112 are electrically connected, the portion of second component 130 from one of the two fastening components 300 to the other of the two fastening components 300 is prevented from functioning as an antenna, and thus emittance of noise to the outside of casing 100 is suppressed.

Furthermore, since first protruding portion 114 and first overlap portion 133 are electrically connected, if static electricity is imparted onto second component 130 from the outside of casing 100, in addition to a route in which static electricity goes toward a nearby fastening component 300, a route that also goes toward the contact part between first protruding portion 114 and first overlap portion 133 is formed, and thus static electricity can be efficiently discharged to the outside of casing 100.

Furthermore, because pressure that causes a firm fit between first component 110 and second component 130 is generated at the three points which are the contact part between first protruding portion 114 and first overlap portion 133, the contact part between third contact portion 138 and third standing portion 115, and the contact part between fourth contact portion 139 and fourth standing portion 116, there is no relative instability between first component 110 and second component 130 and a firm fit can be created therebetween before the fastening by fastening components 300.

It should be noted that the present disclosure is not limited to the above-described embodiments. For example, other embodiments that can be realized by arbitrarily combining structural elements or removing some structural elements described in the present Specification may be embodiments of the present disclosure. Furthermore, variations obtainable through various modifications to the above-described embodiments that can be conceived by a person of ordinary skill in the art without departing from the essence of the present disclosure, that is, the meaning of the recitations in the Claims are included in the present disclosure.

For example, although the case where first protruding portion 114 is provided in first component 110 has been described, first protruding portion 114 may be provided in the inner face of first overlap portion 133 of second component 130. Furthermore, first protruding portion 114 may be provided to each of first component 110 and second component 130.

Furthermore, although the case where connectors that penetrate through case 100 has been described, substate 200 need not include connectors.

Furthermore, the present disclosure may be implemented as an electronic device including casing 100 and substrate 200. For the electronic device, an electronic control unit (ECU) that electronically controls all or part of the functions of mobile body 220, an audio amplifier, an active noise controller, an active sound controller, or the like, may be given as examples.

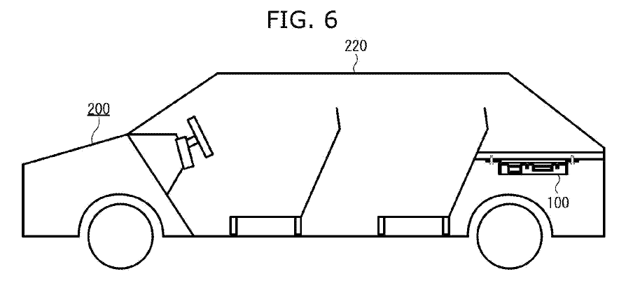

Moreover, as illustrated in FIG. 6, the present disclosure may be implemented as mobile body 220 including casing 100. As mobile body 220, an automobile, an aircraft, a ship, or the like, may be given as examples.

### Conclusion

Casing 100 according to a first aspect is casing 100 that is made of metal and houses substrate 200. Casing 100 includes: first component 110 and second component 130 that are arranged in a thickness direction of substrate 200. First component 110 includes: first face portion 111 that is rectangular and covers first principal face 201 of substrate 200; first standing portion 112 that stands from one edge of first face portion 111 in a crosswise direction of first face portion 111; and second standing portion 113 that stands from an other edge of first face portion 111 in the crosswise direction. Second component 130 includes: second face portion 131 that is rectangular and covers second principal face 202 disposed on a reverse side of first principal face 201; first contact portion 132 that stands from one edge of second face portion 131 in the crosswise direction and overlaps an outer face of first standing portion 112 with contact therebetween; and first overlap portion 133 that stands from an other edge of second face portion 131 in the crosswise direction and overlaps an outer face of second standing portion 113 with a gap therebetween. At least one of second standing portion 113 or first overlap portion 133 includes first protruding portion 114 that maintains the gap between second standing portion 113 and first overlap portion 133 at a predetermined distance and generates pressure between first standing portion 112 and first contact portion 132.

According to the first aspect, the phenomenon in which noise of a predetermined frequency emitted from the housed substrate 200 is emitted to the outside by casing 100 that functions as an antenna can be suppressed by changing the antenna length by electrically connecting first standing portion 112 and first contact portion 132.

Furthermore, since first component 110 and second component 130 conduct via first protruding portion 114 disposed on an opposite side from first standing portion 112, the routes for releasing static electricity imparted from the outside are increased, and thus static electricity can be efficiently discharged.

Casing 100 according to a second aspect is casing 100 according to the first aspect, in which, second component 130 further includes: second overlap portion 134 that stands from one edge of second face portion 131 in a lengthwise direction of second face portion 131 and overlaps one edge of substrate 200 with a gap therebetween, the one edge of substrate 200 being on a same side as the one edge of second face portion 131 in the lengthwise direction; and third overlap portion135 that stands from an other edge of second face portion 131 in the lengthwise direction and overlaps an other edge of substrate 200 with a gap therebetween, the other edge of substrate 200 being on a same side as the other edge of second face portion 131 in the lengthwise direction. Here, second overlap portion 134 includes second protruding portion 136 that protrudes toward substrate 200 and abuts the one edge of substrate 200, and third overlap portion 135 includes third protruding portion 137 that protrudes toward substrate 200 and abuts the other edge of substrate 200.

According to the second aspect, in the lengthwise direction, the positional relationship between first component 110 and second component 130 can be determined via substrate 200. Therefore, contact between first component 110 and second component 130 in the lengthwise direction can be avoided, and thus the effects produced by the electrical connection between first standing portion 112 and first contact portion 132, and the effects produced by first protruding portion 114 can be maintained without causing deterioration.

Casing 100 according to a third aspect is casing 100 according to the first aspect or the second aspect, in which, first standing portion 112 and first contact portion 132 are each disposed at a position that is offset from a center portion in a lengthwise direction of second face portion 131.

According to the third aspect, by placing the connection position between first standing portion 112 and first contact portion 132 at a position that is offset from the center, it is possible to prevent the respective portions extending from the connection portion to either side in the lengthwise direction of second face portion 131 from attaining a length equivalent to 1/4 wavelength of noise of a predetermined frequency emitted from substrate 200, and thus the amount of noise that leaks to the outside can be reduced.

Casing 100 according to a fourth aspect is casing 100 according to any one of the first to third aspects, in which, first component 110 further includes: third standing portion 115 that stands at a position that is aligned with first standing portion 112 in a lengthwise direction of first face portion 111; and fourth standing portion 116 that stands at a position that is aligned with third standing portion 115 in the lengthwise direction, with first standing portion 112 disposed therebetween. Furthermore, second component 130 further includes: third contact portion 138 that overlaps an outer face of third standing portion 115 with contact therebetween; and fourth contact portion 139 that overlaps an outer face of fourth standing portion 116 with contact therebetween.

According to the fourth aspect, a firm fit is created at least at the three points which are: the contact point between third standing portion 115 and third contact portion 138; the contact point between fourth standing portion 116 and fourth contact portion 139; and the position of first protruding portion 114, it is possible to suppress relative instability between first component 110 and second component 130 until first component 110 and second component 130 are joined together.

Casing 100 according to a fifth aspect is casing 100 according to the fourth aspect, in which, first connecter 211 that is to be attached to substrate 200 is disposed between first standing portion 112 and third standing portion 115, and second connecter 212 that is to be attached to substrate 200 is disposed between first standing portion 112 and fourth standing portion 116.

According to the fifth aspect, deterioration of rigidity of casing 100 due to the large holes through which first connector 211 and second connector 212 are to be inserted though can be reduced by the connection points provided at both ends of the large holes.

An electronic device according to a sixth aspect is an electronic device that includes substrate 200 and casing 100 that is made of metal and houses substrate 200. Casing 100 includes: first component 110 and second component 130 that are arranged in a thickness direction of substrate 200. First component 110 includes: first face portion 111 that is rectangular and covers first principal face 201 of substrate 200; first standing portion 112 that stands from one edge of first face portion 111 in a crosswise direction of first face portion 111; and second standing portion 113 that stands from an other edge of first face portion 111 in the crosswise direction. Second component 130 includes: second face portion 131 that is rectangular and covers second principal face 202 disposed on a reverse side of first principal face 201; first contact portion 132 that stands from one edge of second face portion 131 in the crosswise direction and overlaps an outer face of first standing portion 112 with contact therebetween; and first overlap portion 133 that stands from an other edge of second face portion 131 in the crosswise direction and overlaps an outer face of second standing portion 113 with a gap therebetween. At least one of second standing portion 113 or first overlap portion 133 includes first protruding portion 114 that maintains the gap between second standing portion 113 and first overlap portion 133 at a predetermined distance and generates pressure between first standing portion 112 and first contact portion 132.

Mobile body 220 according to a seventh aspect is mobile body 220 that includes an electronic device including substrate 200 and casing 100 that is made of metal and houses substrate 200. Casing 100 includes: first component 110 and second component 130 that are arranged in a thickness direction of substrate 200. First component 110 includes: first face portion 111 that is rectangular and covers first principal face 201 of substrate 200; first standing portion 112 that stands from one edge of first face portion 111 in a crosswise direction of first face portion 111; and second standing portion 113 that stands from an other edge of first face portion 111 in the crosswise direction. Second component 130 includes: second face portion 131 that is rectangular and covers second principal face 202 disposed on a reverse side of first principal face 201; first contact portion 132 that stands from one edge of second face portion 131 in the crosswise direction and overlaps an outer face of first standing portion 112 with contact therebetween; and first overlap portion 133 that stands from an other edge of second face portion 131 in the crosswise direction and overlaps an outer face of second standing portion 113 with a gap therebetween. At least one of second standing portion 113 or first overlap portion 133 includes first protruding portion 114 that maintains the gap between second standing portion 113 and first overlap portion 133 at a predetermined distance and generates pressure between first standing portion 112 and first contact portion 132.

### FURTHER INFORMATION ABOUT TECHNICAL BACKGROUND TO THIS APPLICATION

The disclosure of the following patent application including specification, drawings, and claims is incorporated herein by reference in its entirety: Japanese Patent Application No. 2024-203648 filed on November 22, 2024.

### INDUSTRIAL APPLICABILITY

The present disclosure can be used in a casing that houses a substrate that may emit noise, a casing that is disposed in a place to which static electricity may be imparted from the outside.

1. A casing that is made of metal and houses a substrate, the casing comprising:
a first component and a second component that are arranged in a thickness direction of the substrate, wherein
the first component includes:
a first face portion that is rectangular and covers a first principal face of the substrate;
a first standing portion that stands from one edge of the first face portion in a crosswise direction of the first face portion; and
a second standing portion that stands from an other edge of the first face portion in the crosswise direction,
the second component includes:
a second face portion that is rectangular and covers a second principal face disposed on a reverse side of the first principal face;
a first contact portion that stands from one edge of the second face portion in the crosswise direction and overlaps an outer face of the first standing portion with contact therebetween; and
a first overlap portion that stands from an other edge of the second face portion in the crosswise direction and overlaps an outer face of the second standing portion with a gap therebetween, and
at least one of the second standing portion or the first overlap portion includes a first protruding portion that maintains the gap between the second standing portion and the first overlap portion at a predetermined distance and generates pressure between the first standing portion and the first contact portion.

2. The casing according to claim 1 , wherein the second component further includes:
a second overlap portion that stands from one edge of the second face portion in a lengthwise direction of the second face portion and overlaps one edge of the substrate with a gap therebetween, the one edge of the substrate being on a same side as the one edge of the second face portion in the lengthwise direction; and a third overlap portion that stands from an other edge of the second face portion in the lengthwise direction and overlaps an other edge of the substrate with a gap therebetween, the other edge of the substrate being on a same side as the other edge of the second face portion in the lengthwise direction,the second overlap portion includes a second protruding portion that protrudes toward the substrate and abuts the one edge of the substrate, and
the third overlap portion includes a third protruding portion that protrudes toward the substrate and abuts the other edge of the substrate.

3. The casing according to claim 1, wherein the first standing portion and the first contact portion are each disposed at a position that is offset from a center portion in a lengthwise direction of the second face portion.

4. The casing according to claim 1, wherein the first component further comprises:
a third standing portion that stands at a position that is aligned with the first standing portion in a lengthwise direction of the first face portion; and
a fourth standing portion that stands at a position that is aligned with the third standing portion in the lengthwise direction, with the first standing portion disposed therebetween, and
the second component further includes:
a third contact portion that overlaps an outer face of the third standing portion with contact therebetween; and
a fourth contact portion that overlaps an outer face of the fourth standing portion with contact therebetween.

5. The casing according to claim 4, wherein
a first connecter that is to be attached to the substrate is disposed between the first standing portion and the third standing portion, and
a second connecter that is to be attached to the substrate is disposed between the first standing portion and the fourth standing portion.

6. The casing according to claim 2, wherein
the first standing portion and the first contact portion are each disposed at a position that is offset from a center portion in a lengthwise direction of the second face portion.

7. The casing according to claim 2, wherein
the first component further comprises:
a third standing portion that stands at a position that is aligned with the first standing portion in a lengthwise direction of the first face portion; and
a fourth standing portion that stands at a position that is aligned with the third standing portion in the lengthwise direction, with the first standing portion disposed therebetween, and
the second component further includes:
a third contact portion that overlaps an outer face of the third standing portion with contact therebetween; and
a fourth contact portion that overlaps an outer face of the fourth standing portion with contact therebetween.

8. The casing according to claim 7, wherein
a first connecter that is to be attached to the substrate is disposed between the first standing portion and the third standing portion, and
a second connecter that is to be attached to the substrate is disposed between the first standing portion and the fourth standing portion.

9. An electronic device comprising:
a substrate; and
a casing that is made of metal and houses the substrate, wherein
the casing includes a first component and a second component that are arranged in a thickness direction of the substrate,
the first component includes:
a first face portion that is rectangular and covers a first principal face of the substrate;
a first standing portion that stands from one edge of the first face portion in a crosswise direction of the first face portion; and
a second standing portion that stands from an other edge of the first face portion in the crosswise direction, the second component includes:
a second face portion that is rectangular and covers a second principal face disposed on a reverse side of the first principal face;
a first contact portion that stands from one edge of the second face portion in the crosswise direction and overlaps an outer face of the first standing portion with contact therebetween; and
a first overlap portion that stands from an other edge of the second face portion in the crosswise direction and overlaps an outer face of the second standing portion with a gap therebetween, and
at least one of the second standing portion or the first overlap portion includes a first protruding portion that maintains the gap between the second standing portion and the first overlap portion at a predetermined distance and generates pressure between the first standing portion and the first contact portion.

10. A mobile body comprising:
an electronic device including a substrate and a casing that is made of metal and houses the substrate, wherein
the casing includes a first component and a second component that are arranged in a thickness direction of the substrate,
the first component includes:
a first face portion that is rectangular and covers a first principal face of the substrate;
a first standing portion that stands from one edge of the first face portion in a crosswise direction of the first face portion; and
a second standing portion that stands from an other edge of the first face portion in the crosswise direction, the second component includes:
a second face portion that is rectangular and covers a second principal face disposed on a reverse side of the first principal face;
a first contact portion that stands from one edge of the second face portion in the crosswise direction and overlaps an outer face of the first standing portion with contact therebetween; and a first overlap portion that stands from an other edge of the second face portion in the crosswise direction and overlaps an outer face of the second standing portion with a gap therebetween, and
at least one of the second standing portion or the first overlap portion includes a first protruding portion that maintains the gap between the second standing portion and the first overlap portion at a predetermined distance and generates pressure between the first standing portion and the first contact portion.
